(19) United States
(12) Patent Application Publication
(10) Pub. No.: US 2014/0043784 A1
(43) Pub. Date: Feb. 13, 2014

(54) ELECTRONIC DEVICE WITH SECURING ASSEMBLY FOR EXPANSION CARD

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: YUN-LUNG CHEN, New Taipei (TW); GANG SU, Wuhan (CN); ZHI-QIANG LI, Wuhan (CN); ZHI-LONG LI, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/897,422

(22) Filed: May 19, 2013

(30) Foreign Application Priority Data
Aug. 7, 2012 (CN) 2012102782625

(51) Int. Cl. G06F 1/18; H05K 7/12

(52) U.S. Cl. CPC G06F 1/185; H05K 7/12
USPC 361/801

(57) ABSTRACT

An electronic device includes a chassis, a motherboard, an expansion card, and a securing member. The chassis includes a bottom wall and a sidewall substantially perpendicular to the bottom wall. Two engaging slots are defined in the sidewall. The motherboard is located on the bottom wall. The expansion card is plugged into the motherboard. The securing member includes a resilient board and two feet located on the resilient board. The resilient board is configured to deform to engage the two feet in the two engaging slots and retain the expansion card to the motherboard.

### BACKGROUND

1. Technical Field

The present disclosure relates to an electronic device with a securing assembly for retaining expansion cards.

2. Description of Related Art

Computers often include expansion cards, such as PCI cards and graphics cards, for example, for enhancing capabilities of the computer system. The expansion cards are often fastened in the computers with screws at one side. However, installing screws to fix the expansion cards is very laborious and time-consuming, and having only one side of the expansion card fastened may not provide enough stability. Therefore, there is room for improvement within the art.

### BRIEF DESCRIPTION OF THE DRAWINGS

FIG. 1 is a partially exploded, schematic view of one embodiment of an electronic device.

FIG. 2 is an enlarged view of a securing member of the electronic device FIG. 1.

FIG. 3 is similar to FIG. 2, but shows from another aspect.

FIG. 4 is an assembled view of the electronic device of FIG. 1.

FIG. 5 is an enlarged view of the circled portion V of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

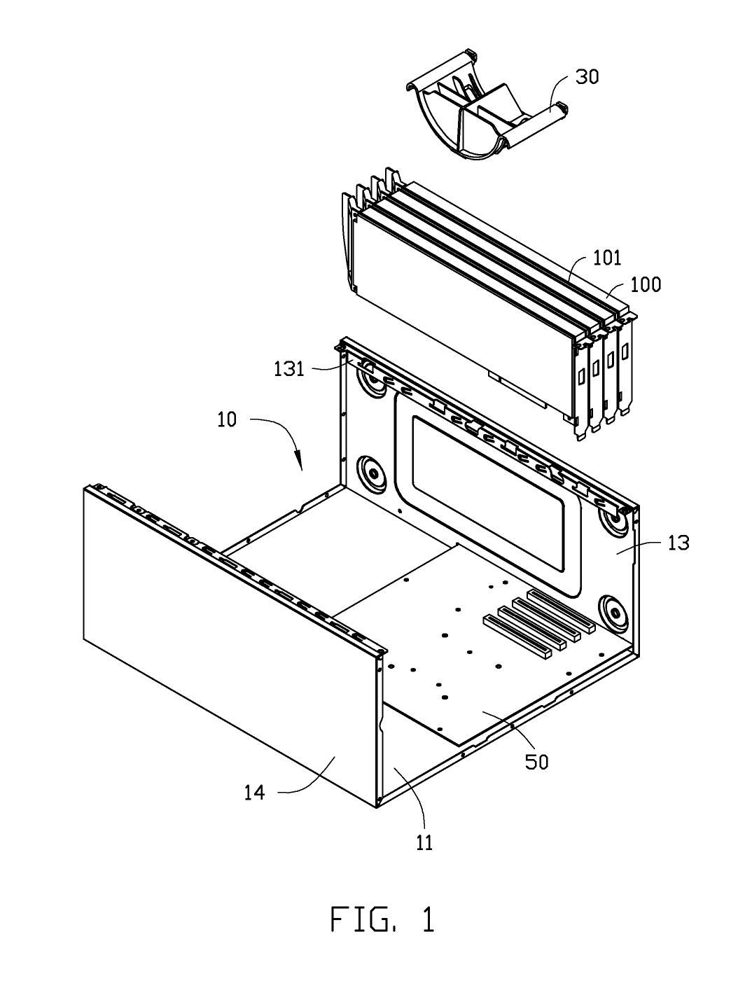

FIG. 1 illustrates one embodiment of an electronic device. The electronic device includes a securing assembly to retain a plurality of expansion cards 100. Each expansion card 100 includes a printed circuit board 101. The printed circuit boards 101 can be plugged into a motherboard 50. The securing assembly includes a chassis 10 and a securing member 30.

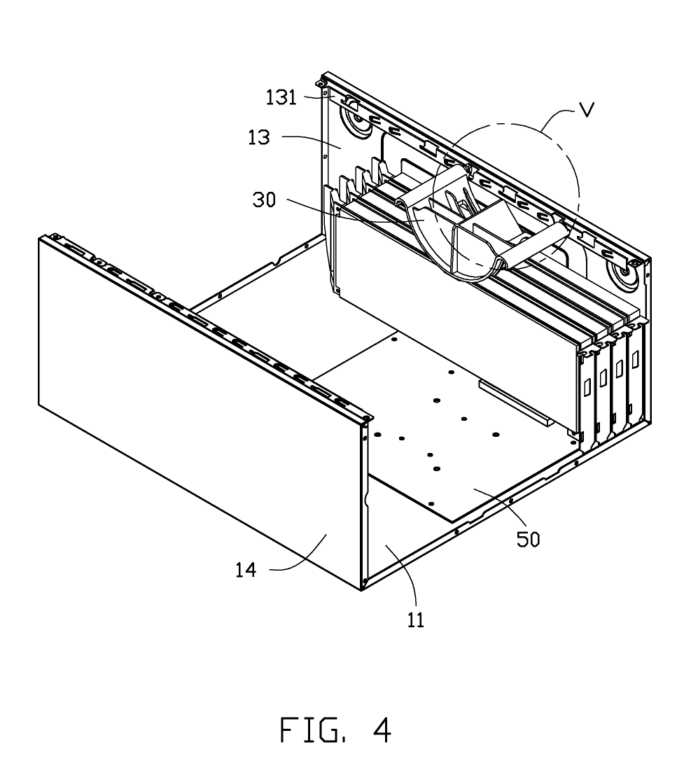

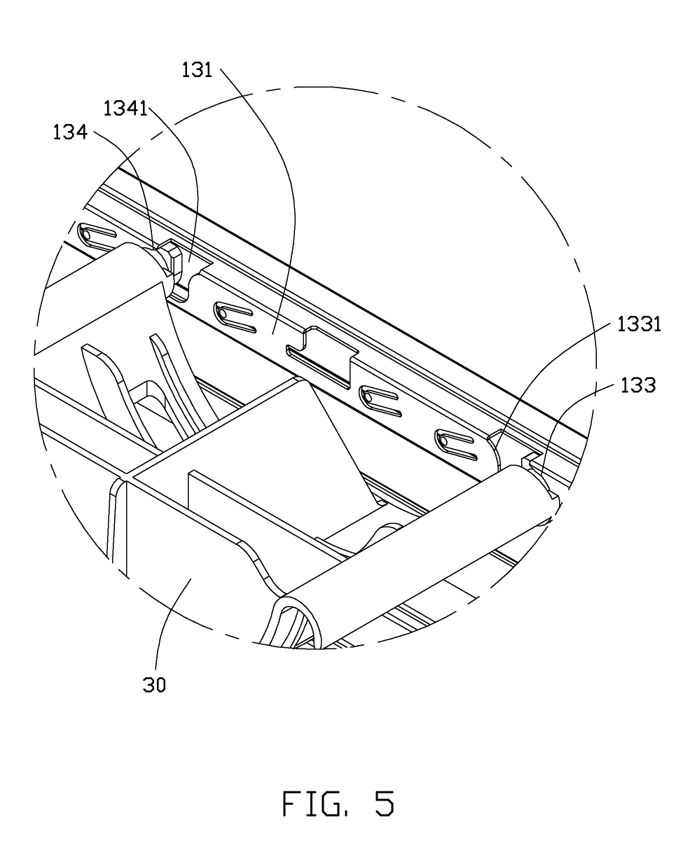

Referring to FIG. 4 and FIG. 5, the chassis 10 includes a bottom wall 11 and two sidewalls 13, 14. The two sidewalls 13, 14 are substantially perpendicular to the bottom wall 11. A flange 131 extends from a top edge of the sidewall 13 and is folded back to be substantially parallel to the sidewall 13. A first engaging slot 1331 and a second engaging slot 1341 are defined in the flange 131. The first engaging slot 1331 and the second engaging slot 1341 are oblique relative to a vertical direction and extend substantially towards two opposite directions. The flange 131 includes a first locking portion 133 located on one side of the first engaging slot 1331, and a second locking portion 134 located on one side of the second engaging slot 1341.

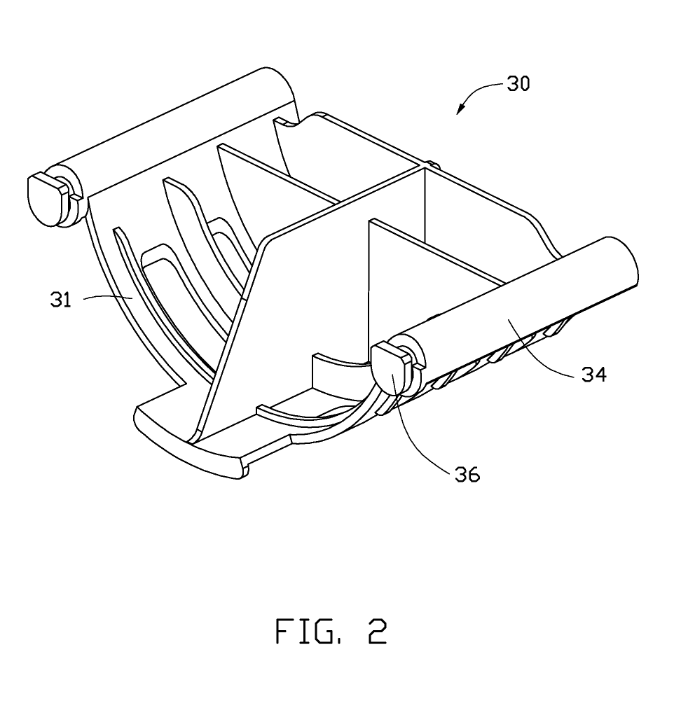

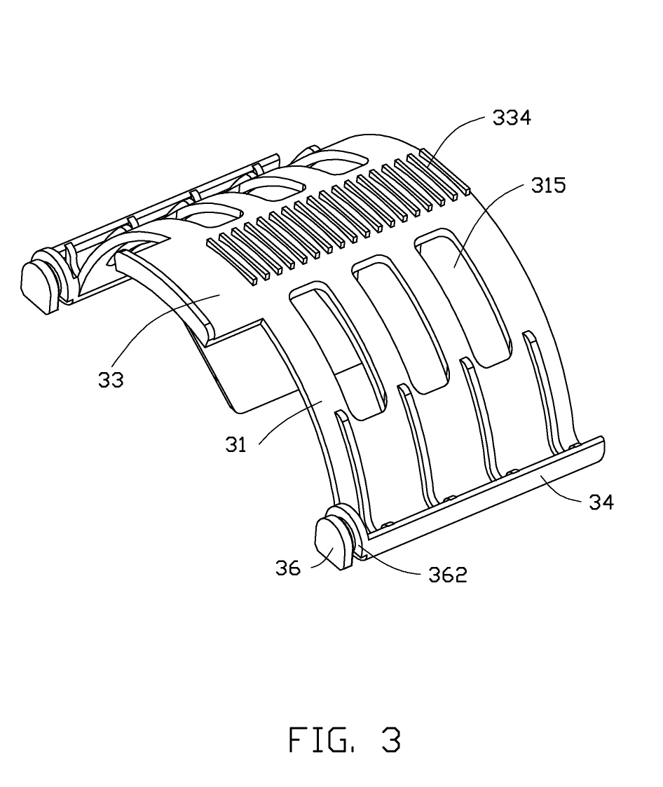

FIG. 2 and FIG. 3 illustrate the securing member 30 from different aspects. The securing member 30 includes a resilient board 31 and two feet 36. The resilient board 31 is arched. Two roller edges 34 are located on two opposite sides of the resilient board 31 for facilitating operation. Each foot 36 is located on a lateral side of each roller edge 34. An annular groove 362 is defined between each foot 36 and each roller edge 34. The resilient board 31 includes a retaining portion 33 to retain the expansion card 100. A plurality of restriction ribs 334 protrudes from the retaining portion 33. The ribs 334 are parallel to each other. A plurality of vents 315 is defined in the resilient board 31 to provide heat dissipation for the expansion card 100. The securing member 30 can be integrally formed.

Referring to FIG. 4 and FIG. 5, in assembly, the motherboard 50 is located on the bottom wall 11 of the chassis 10. The expansion cards 100 are plugged into the motherboard 50 and are substantially parallel to the sidewall 13.

To install the expansion cards 100 in the chassis 10, the two roller edges 34 of the securing member 30 are pressed towards each other to compress the resilient board 31. The securing member 30 is moved to insert the two feet 36 into the first engaging slot 1331 and the second engaging slot 1341 respectively. The resilient board 31 is released, and the resilient board 31 rebounds to an original state. The two feet 36 are thus engaged in the first engaging slot 1331 and the second engaging slot 1341. The two feet 36 abut the first locking portion 133 and the second locking portion 134. The securing member 30 is secured to the sidewall 13. The retaining portion 33 abuts and presses down the expansion cards 100. The ribs 334 space the expansion cards 100 from each other. Thereby, the expansion cards 100 are retained to the chassis 10.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device comprising:
a chassis comprising a bottom wall and a sidewall substantially perpendicular to the bottom wall, two engaging slots defined in the sidewall;
a motherboard located on the bottom wall;
an expansion card plugged to the motherboard;
a securing member comprising a resilient board and two feet located on the resilient board, and the resilient board being configured to be deformed to engage the two feet with the two engaging slots and retain the expansion card to the motherboard.

2. The electronic device of claim 1, wherein the resilient board is curved.

3. The electronic device of claim 1, wherein the resilient board comprises two roller edges on two opposite sides thereof.

4. The electronic device of claim 3, wherein the two feet are located on the two roller edges.

5. The electronic device of claim 4, wherein each of the two feet is located on a lateral side of each of the two roller edges, and an annular groove is defined between each of the two feet and each of the two roller edges to engage with the sidewall.

6. The electronic device of claim 1, wherein the securing member is integrally formed.

7. The electronic device of claim 1, wherein the resilient board comprises a retaining portion to retain the expansion card, and a plurality of parallel restriction ribs protrudes from the retaining portion.

8. The electronic device of claim 1, wherein a plurality of vents is defined in the resilient board.

9. The electronic device of claim 1, wherein a flange is located on the sidewall, and the two engaging slots are defined in the flange.

10. The electronic device of claim 9, wherein the two engaging slots are oblique to each other, and the two engaging slots extend substantially towards opposite directions.

11. An securing assembly for an expansion card comprising:
a chassis comprising a sidewall, and two engaging slots defined in the sidewall;
a securing member comprising a resilient board and two feet located on the resilient board, and the resilient board being configured to deform to engage the two feet with the two engaging slots to retain the expansion card.

12. The securing assembly of claim 11, wherein the resilient board is curved.

13. The securing assembly of claim 11, wherein the resilient board comprises two roller edges on two opposite sides thereof.

14. The securing assembly of claim 13, wherein the two feet are located on the two roller edges.

15. The securing assembly of claim 14, wherein each of the two feet is located on a lateral side of each of the two roller edges, and an annular groove is defined between each of the two feet and each of the two roller edges to engage with the sidewall.

16. The securing assembly of claim 11, wherein the securing member is integrally formed.

17. The securing assembly of claim 11, wherein the resilient board comprises a retaining portion to retain the expansion card, and a plurality of parallel restriction ribs protrudes from the retaining portion.

18. The securing assembly of claim 11, wherein a plurality of vents is defined in the resilient board.

19. The securing assembly of claim 11, wherein a flange is located on the sidewall, and the two engaging slots are defined in the flange.

20. The securing assembly of claim 19, wherein the two engaging slots are oblique to each other, and the two engaging slots extend substantially towards opposite directions.
